(19) United States
(12) Patent Application Publication
(10) Pub. No.: US 2026/0155758 A1
(43) Pub. Date: Jun. 4, 2026

(54) POWER SUPPLY DEVICE AND DRIVING METHOD THEREOF

(71) Applicant: Jong Hak BAEK, Seoul (KR)

(72) Inventor: Jong Hak BAEK, Seoul (KR)

(21) Appl. No.: 18/052,435

(22) Filed: Nov. 3, 2022

Related U.S. Application Data
(63) Continuation of application No. PCT/KR20/06904, filed on May 28, 2020.

(30) Foreign Application Priority Data
May 8, 2020 (KR) 10-2020-0055486

(51) Int. Cl. H02M 7/25; H02M 1/00; H02M 1/32; H03K 17/08

(52) U.S. Cl. CPC H02M 7/25; H02M 1/0083; H02M 1/32; H03K 17/08; H03K 2017/0803

(57) ABSTRACT

A power supply device comprises: a switching converter using input power of AC or DC supplied through an input power unit, having a switch, and generating output power by using an on-off action of the switch; a driving controller generating a first control signal for controlling the on-off action of the switch of the switching converter; a level converter receiving the first control signal from the driving controller and outputting a second control signal to the switch of the switching converter, and a voltage generator supplying a power source to at least one among the switching converter, the driving controller, and the level converter.

### CROSS-REFERENCE TO RELATED APPLICATION

The present application is a continuation of International Patent Application No. PCT/KR2020/006904, filed on May 28, 2020, which is based upon and claims the benefit of priority to Korean Patent Application No. 10-2020-0055486 filed on May 8, 2020. The disclosures of the above-listed applications are hereby incorporated by reference herein in their entirety.

### BACKGROUND

### 1. Technical Field

The present disclosure relates to a power supply device used in an electronic device and a driving method thereof.

### 2. Description of Related Art

A switched mode power supply (SMPS), a power supply device for an LED lighting device, breaks down in a case in which the SMPS is exposed to a high-level radioactive environment for a predetermined time or more. In a case in which the SMPS is destroyed, power is not supplied to the LED lighting device, and it causes a fatal problem that the lighting device no longer operates. Therefore, in order to use an electronic device, such as an LED lighting device, the problem that the power supply device in the LED lighting device is destroyed should be solved.

For the description of the present disclosure, a nuclear power plant and an LED lighting device are used as examples for a place and an electronic device, but they are not intended to limit the present disclosure. All electronic devices require a power supply device for supplying power. Therefore, it should be understood that the present disclosure relates to a power supply device and a driving method for an electronic device used in a location in which environmental stress may be generated due to distinct characteristics of a space.

### SUMMARY

The present disclosure has been made to solve the above-mentioned problems occurring in the prior art, and in an aspect of the present disclosure, an object of the present disclosure is to provide a power supply device and a driving method thereof, which are used in an electronic device used in a location in which environmental stress may be generated, such as a space in which cosmic rays are high due to solar activity, such as space, or a location in which electromagnetic waves or radiation are strong, such as a nuclear reactor containment building of a nuclear power plant.

Another object of the present disclosure is to provide a power supply device capable of stably operating by preventing malfunctioning and damage caused by environmental stress, and a driving method thereof.

A further object of the present disclosure is to provide a power supply device capable of reducing a leakage current of a semiconductor switch element, and a driving method thereof.

The aspects of the present disclosure are not limited to those mentioned above, and other aspects not mentioned herein will be clearly understood by those skilled in the art from the following description.

To accomplish the above-mentioned objects, according to an aspect of the present disclosure, there is provided a power supply device including: a switching converter using input AC or DC power supplied through an input power unit, having a switch, and generating output power by using an on-off action of the switch; a driving controller generating a first control signal for controlling the on-off action of the switch of the switching converter; a level converter receiving the first control signal from the driving controller, outputting a second control signal to the switch of the switching converter, and including a level shifter generating the second control signal having a modified voltage level by converting a voltage of the first control signal for turning the switch off to have a voltage level lower than source terminal voltage of the switch in a case in which the switch of the switching converter is an N-type and by converting the voltage to voltage higher than the source terminal voltage of the switch in a case in which the switch of the switching converter is a P-type; and a voltage generator supplying a power source to at least one among the switching converter, the driving controller, and the level converter.

### BRIEF DESCRIPTION OF THE DRAWINGS

FIG. 1 is a block diagram of a power supply device according to an embodiment of the present disclosure.

FIG. 2 is a circuit diagram of a boost converter according to a first embodiment of the present disclosure.

FIG. 3 is a circuit diagram of a conventional boost converter.

FIG. 4 is a waveform diagram illustrating a simulation result before a conventional boost converter circuit is exposed to a radioactive environment.

FIG. 5 is a waveform diagram illustrating a simulation result after a conventional boost converter circuit is exposed to a radioactive environment.

FIG. 6 is a waveform diagram illustrating a simulation result after a boost converter circuit according to the first embodiment of the present disclosure is exposed to a radioactive environment.

FIGS. 7 and 8 are circuit diagrams illustrating a case in which a level shifter is used in a level converter implementing method according to an embodiment of the present disclosure.

FIG. 9 is a detailed circuit diagram of the level shifter of FIG. 7.

FIG. 10 is a circuit diagram illustrating a case in which a comparator is used in the level converter implementing method according to an embodiment of the present disclosure.

FIG. 11 is a circuit diagram illustrating a case in which a multiplexer is used in the level converter implementing method according to an embodiment of the present disclosure.

FIG. 12 is a circuit diagram illustrating a case in which a level converter is embedded in a driving control unit in the level converter implementing method according to an embodiment of the present disclosure.

FIG. 13 is a circuit diagram illustrating a flyback converter according to a second embodiment of the present disclosure.

FIG. 14 is a circuit diagram illustrating a buck converter according to a third embodiment of the present disclosure.

### DETAILED DESCRIPTION

Advantages and features of the present disclosure and methods accomplishing the advantages and features will become apparent from the following detailed description of exemplary embodiments with reference to the accompanying drawings. However, the present disclosure is not limited to exemplary embodiment disclosed herein but will be implemented in various forms. The exemplary embodiments are provided so that the present disclosure is completely disclosed, and a person of ordinary skilled in the art can fully understand the scope of the present disclosure. Therefore, the present disclosure will be defined only by the scope of the appended claims.

Terms used in the specification are used to describe specific embodiments of the present disclosure and are not intended to limit the scope of the present disclosure. In the specification, the terms of a singular form may include plural forms unless otherwise specified. It should be also understood that the terms of ‘include’ or ‘have’ in the specification are used to mean that there is no intent to exclude existence or addition of other components besides components described in the specification. In the detailed description, the same reference numbers of the drawings refer to the same or equivalent parts of the present disclosure, and the term “and/or” is understood to include a combination of one or more of components described above. It will be understood that terms, such as “first” or “second” may be used in the specification to describe various components but are not restricted to the above terms. The terms may be used to discriminate one component from another component. Therefore, of course, the first component may be named as the second component within the scope of the present disclosure.

Unless otherwise defined, all terms (including technical and scientific terms) used herein have the same meaning as commonly understood by those skilled in the technical field to which the present disclosure pertains. It will be further understood that terms, such as those defined in commonly used dictionaries, should not be interpreted in an idealized or overly formal sense unless expressly so defined herein.

The term, “unit,” used in the present disclosure means a hardware element, such as software, FPGA, or ASIC, and the “unit” performs some roles. However, the term, “unit,” is not limited to software or hardware. The “unit” may be configured in an addressable storage medium or may be configured to play one or more processors. Therefore, as an example, a “unit” includes elements, such as software elements, object-oriented software elements, class elements, and task elements, processes, functions, attributes, procedures, subroutines, segments of program codes, drivers, firmware, microcode, circuits, data, databases, data structures, tables, arrays, and variables. Functions provided within the elements and “units” may be combined with a smaller number of elements and “units” or may be further divided into additional elements and “units.”

The conventional art to solve the problem that a power supply device of an electronic device used in a radiological environment approached the passive avoidance method to protect parts vulnerable to radiation among parts of the power supply device from being exposed to radiation by minimizing exposure to radiation. However, the conventional radiation shielding method has a limitation that it is partially applicable only in an environment a radiation absorbed dose lower than a predetermined level since it is impossible to perfectly shield radiation. Therefore, the conventional art requires a method of solving the problem more securely.

In order to describe embodiments of the present disclosure proposed to solve the problem, the cause for destruction of the power supply device in the high-level radioactive environment is as follows. In a case in which various parts of the power supply device are exposed to the radioactive environment, electrical characteristics of the parts are changed because of an influence of radiation. Accordingly, when overcurrent flows, a switch element is destroyed, and the power supply device is also destroyed and does not work.

Preferred embodiments for implementing the present disclosure on the basis of the cause analysis result will be described with reference to the drawings.

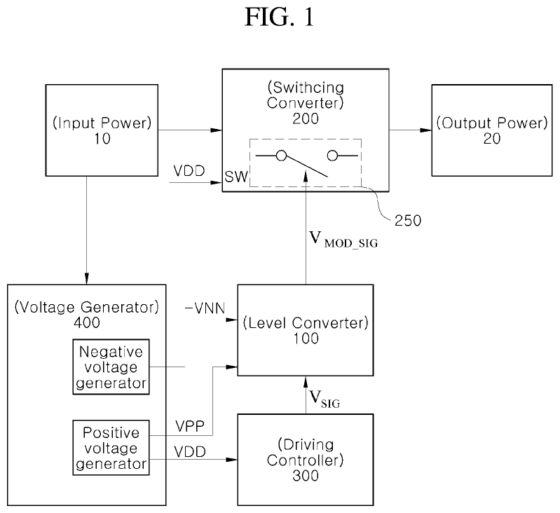

FIG. 1 is a block diagram of a power supply according to an embodiment of the present disclosure. The power supply device according to the embodiment includes: a switching converter 200 using input power of AC or DC supplied through an input power unit 10, having a switch (SW) 250, and generating output power by using an action of the switch 250; a driving controller 300 generating a control signal (VSIG) for controlling the action of the switch 250 of the switching converter 200; a level converter 100 disposed between the driving controller 300 and the switch 250 of the switching converter 200 and converting the control signal (VSIG) generated by the driving controller 300 into a modified control signal (VMOD_SIG) by changing a voltage level of the control signal (VSIG) into a modified voltage level so as to block the switch 250 of the switching converter 200 and reduce a leakage current of the switch; and a voltage generator 400 supplying power required to the switching converter 200 and the driving controller 300.

In this instance, the switch 250 of the switching converter 200 can be implemented by a semiconductor switch element. The semiconductor switch element is implemented by an N-type or a P-type metal-oxide-semiconductor field effect transistor (hereinafter, called MOSFET), an NPN-type or a PNP-type bipolar junction transistor (hereinafter, called BJT), or an insulated gate bipolar transistor (IGBT).

The switching converter 200 includes a power supply device of various types having the switch 250 and a structure of operating the switch 250 by the received modified control signal to send output power supply aimed. For instance, the power supply device of various types may be an SMPS and a linear regulator. For instance, the SMPS includes a method of using an inductor or a capacitor, or an uninsulated type and an insulated type according to the use of a transformer. The uninsulated converter includes a buck converter, a boost converter, a buck-boost converter, a CUK converter, and a SEPIC converter, and the insulated method includes a flyback converter, a push-pull converter, and an insulated CUK converter.

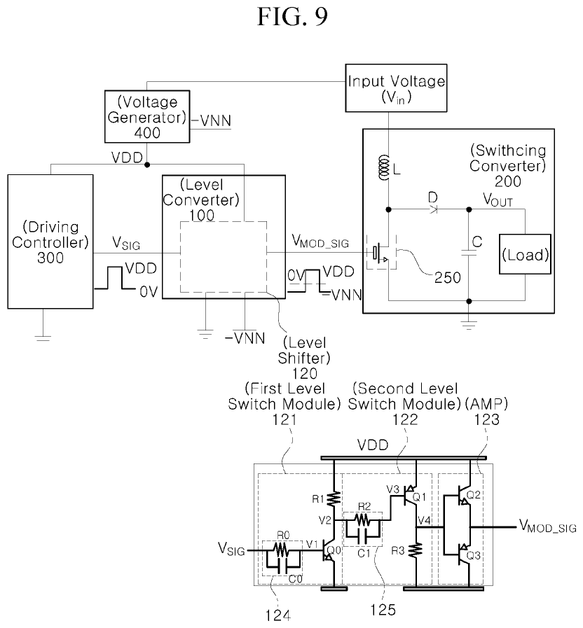

In this instance, the level converter 100 is configured to include a level shifter 120 (See FIG. 9), and it will be described in detail later. Moreover, in several embodiments, a circuit of the level converter 100 may be embedded in the driving controller 300.

In this instance, the driving controller 300 generates a control signal for controlling the switching converter 200.

In this instance, the voltage generator 400 generates power required for the level converter 100, the switching converter 200, and the driving controller 300. According to the type of the switch 250 of the switching converter 200, in a case in which the switch 250 is a P-type MOSFET, the voltage generator generates VDD which is a positive voltage, and supplies it to the switching converter 200 and the driving controller 300. In a case in which the switch 250 is an N-type MOSFET, the voltage generator 400 generates a positive voltage VDD and supplies it to the level converter 100, the switching converter 200, and the driving controller 300. Additionally, the voltage generator generates −VNN, which is lower than a source terminal voltage of the N-type MOSFET switch, and supplies it to the level converter 100. In this instance, the positive voltage VDD supplied to the level converter 100 according to the characteristics of the circuit is supplied to another positive voltage VPP.

Referring to FIG. 1, a driving method of the power supply device according to an embodiment of the present disclosure will be described. The driving method of the power supply device according to an embodiment of the present disclosure includes the operations of: inputting power supply by an input power unit; generating and supplying power required for operation of the switching converter 200, the driving controller 300 and the level converter 100 by the voltage generator 400; generating a control signal for controlling operation of the switch 250 of the switching converter 200 by the driving controller 300; changing a voltage level of the control signal generated by the driving controller while passing the level converter 100; and operating the switch 250 of the switching converter 200 by receiving power from the input power unit by the switching converter 200 and a modified control signal having a voltage level changed while passing the level converter 100 to generate output power.

In this instance, in operation of changing the voltage level of the control signal generated by the driving controller, to block the switch 250 of the switching converter 200 and reduce a leakage current of the switch, the voltage level of the control signal generated by the driving controller 300 in a blocking section is changed to be lower than a voltage of a source terminal of the switch 250 in a case in which the switch 250 of the switching converter 200 is an N-type MOSFET, and is changed to be higher than the voltage of the source terminal of the switch 250 in a case in which the switch 250 of the switching converter 200 is a P-type MOSFET, thereby applying the changed voltage to a gate terminal of the switch 250 of the switching converter 200.

The operation of the preferred embodiment of the present disclosure will be described in more detail with reference to a boost converter as a first embodiment. The boost converter among various types of power supply devices is provided to help in an understanding of the present inventive concept, and is not intended to limit the present disclosure. In addition, descriptions of portions that are the same as or similar to those described above may be omitted.

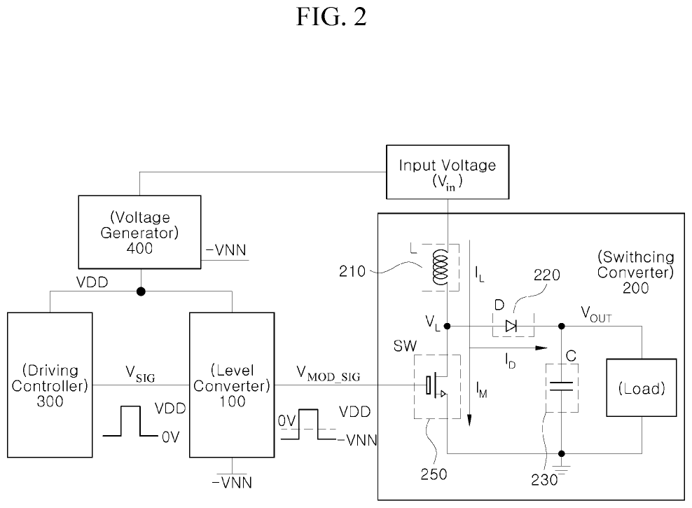

FIG. 2 is a circuit diagram of the boost converter according to the first embodiment of the present disclosure. Referring to FIG. 2, the boost converter according to the embodiment of the present disclosure will be described. The switching converter 200 uses an N-type MOSFET as a first switch (SW) device 250 controlling a flow of a current and uses a diode (D) 220 as a second switch element operating in a complementary relationship with the first switch element and controlling a flow of a current. The switching converter 200 includes an inductor L) 210 and a capacitor (C) 230 storing energy, a driving controller 300 generating a control signal to control the first switch element 250, a level converter 100 changing a swing voltage level of the control signal (VSIG) generated by the driving controller and generating a modified control signal (VMOD_SIG) of a modified voltage level, and a voltage generator 400 supplying power to the driving controller 300 and the level converter 100.

The boost converter controls an on-off duty ratio of the switch 250 through the control signal by the SMPS boosting and outputting an input voltage to determine a boost level of an output voltage (VOUT) on the basis of the input voltage (Vin).

$$VOUT = \frac{1}{1 - D} * VIN ( D : duty ratio ) \qquad [ Equation 1 ]$$

The input voltage (Vin) is AC voltage or DC voltage. In a case in which the input voltage is AC voltage, the input power unit may further include a rectifier (not shown). The rectifier may be variously implemented according to purposes of use. In the present embodiment, as an example, DC voltage is used.

The operation of the boost converter according to the embodiment will be described below. The voltage generator 400 generates power and supplies power to the driving controller 300 and the level converter 100. The driving controller 300 generates a control signal (VSIG) to control the switch 250 of the switching converter 200. The generated control signal (VSIG) is converted into a modified control signal (VMOD_SIG) of a voltage level modified through the level converter 100 to control the switch 250 of the switching converter 200. In this instance, in a case in which the switch 250 is turned on by the modified control signal (VMOD_SIG) of the modified voltage level, energy is stored in the inductor 210 while a current (IL) passing the inductor 210 from the input voltage (Vin) does not flow toward the diode 220 except for the leakage current of the diode 220 (IL≈0), but a current (IM) flows only to the switch 250 (IL≈ID). Thereafter, in a case in which the switch 250 is blocked by the modified control signal, the current (IM) flowing to the switch 250 does not flow, but the output voltage (Vout) is boosted by adding the energy stored in the inductor 200 and the input voltage (Vin) while the current (ID) passing the diode 220 flows (IL≈ID). In this instance, the capacitor 230 stores the output voltage (Vout) and is stably supplied to a load.

In order to describe the present disclosure in more detail, the phenomenon generated in a case in which the boost converter operates in a high-level radioactive environment in comparison with a conventional boost converter circuit.

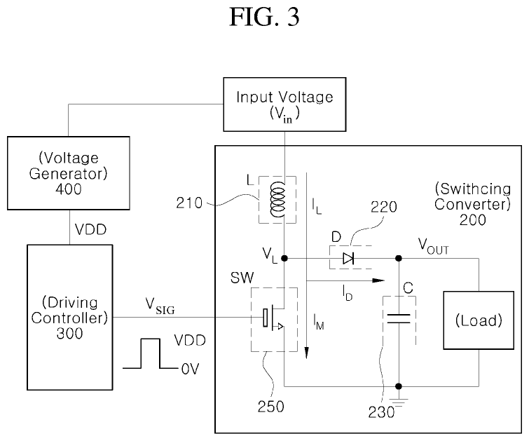

FIG. 3 is a circuit diagram illustrating the conventional boost converter. Compared with the boost converter circuit according to the first embodiment of the present disclosure illustrated in FIG. 2, the conventional boost converter circuit does not include the level converter 100, and the voltage generator 400 does not generate a negative voltage but generates only a positive voltage required for the driving controller 300. Therefore, the control signal (VSIG) generated by the driving controller 300 is directly connected to a gate of the switch 250 of the switching converter 200 to control the operation, and in this instance, the control signal (VSIG) swings from 0V to VDD.

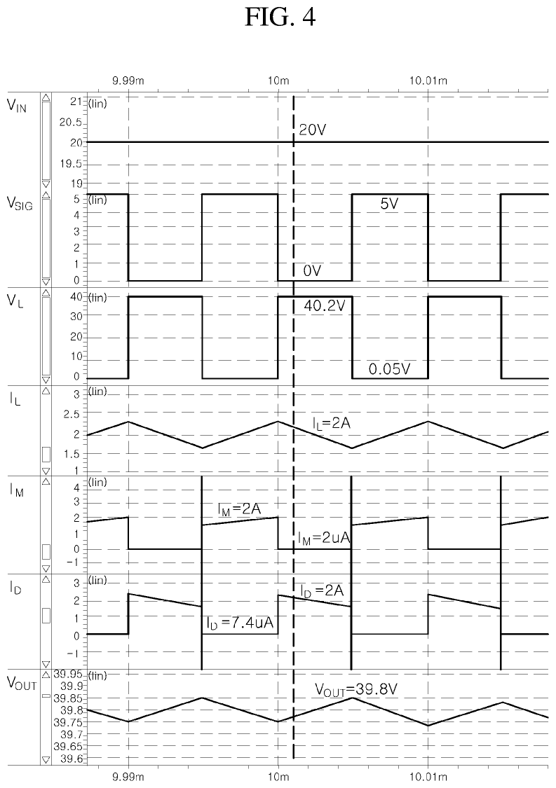

FIG. 4 is a waveform diagram illustrating a simulation result before a conventional boost converter circuit is exposed to a radioactive environment. The switch 250 used in the simulation is an N-type MOSFET. Referring to FIG. 4, characteristics according to the operation of the circuit will be described. The input voltage (Vin) is 20V, and the voltage generator 400 generates VDD of 5V and supplies it to the driving controller 200. The driving controller 300 generates a control signal (VSIG) having 50% of the on-off duty ratio and swinging from 0V to 5V to operate the switch 250 of the switching converter 200, thereby outputting the output voltage (Vout) of about 39.8V, twice the input voltage. In this instance, the current (IL, IL=IM+ID) flowing through the inductor 200 is about 2 A, and the entire boost converter circuits operate normally.

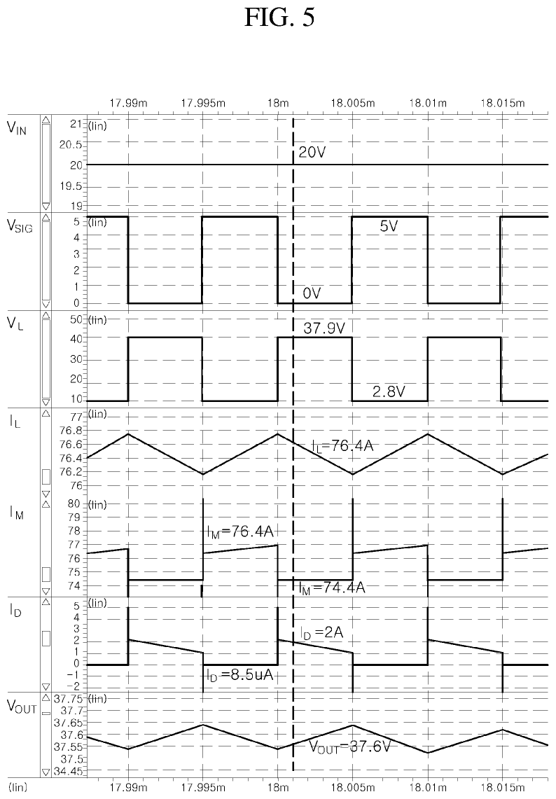

FIG. 5 is a waveform diagram illustrating a simulation result after a conventional boost converter circuit is exposed to a radioactive environment. The electrical characteristics of the semiconductor device exposed to radiation are changed. Electrical characteristics of the N-type MOSFET, which is the switch 250, was actually measured after performing a radioactive environment exposure experiment, and the measurement result was reflected in the simulation. According to the simulation result illustrated in FIG. 5, the current (IL) flowing through the inductor 210 was about 76.4 A, which was dozens of times as much as the current before the radioactive environment exposure experiment of FIG. 4. The current was increased since the current (ID) flowing through the diode 220 was about 2 A, which was similar to the current in a normal condition of FIG. 4 but the current (IM) flowing through the switch 250 was increased by 74.4 A compared with the result of FIG. 4. The reason is that the control signal (VSIG) generated by the driving controller 300 controls the switch 250 while swinging from 0V to 5V but the electrical characteristics of the N-type MOSFET of the switch 250 are changed by radiation, and thus, the switch 250 is not blocked even in the blocking section and the current flows continuously. In the simulation, destruction of the switch 250 was not modeled. Accordingly, the current continuously flowed to the switch 250 even in the blocking section of the switch 250, but the output voltage (Vout) was about 37.6V which was slightly lower than the simulation result before the radioactive environment exposure experiment of FIG. 4. However, in an actual circuit operation, overcurrent flowed to the switch 250 in the blocking section of the switch 250, and thus, the switch 250 was destroyed and the entire SMPS system was not operated.

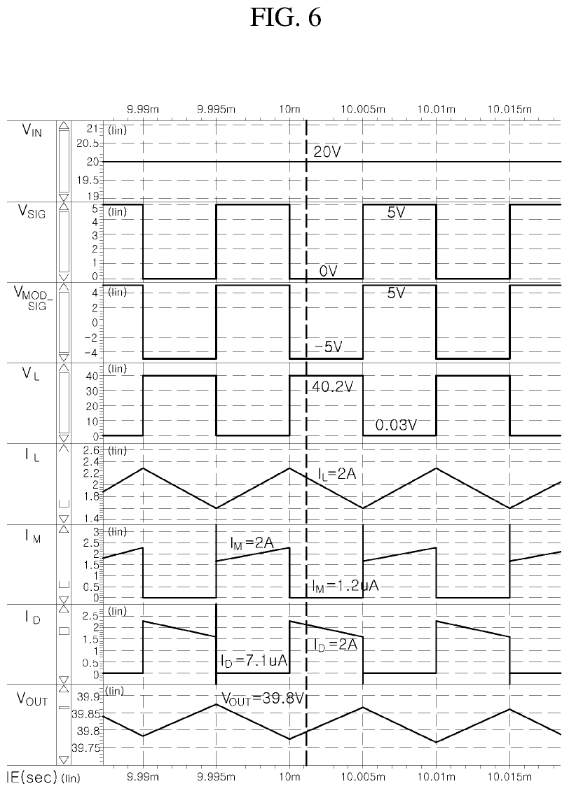

FIG. 6 is a waveform diagram illustrating a simulation result after a boost converter circuit according to the first embodiment of the present disclosure of FIG. 2 is exposed to a radioactive environment. The electrical characteristics of the N-type MOSFET, which is the switch 250 used in the simulation, had the same value as the simulation of FIG. 5. The result of the measurement obtained after the radioactive environment exposure experiment was carried out actually was reflected to the simulation of FIG. 6. Although the value of the electrical characteristics of the N-type MOSFET of the switch 250, which was changed by radiation, was reflected, unlike FIG. 5, the boost converter operated normally. As illustrated in FIG. 6, the voltage generator 400 generates a positive voltage of 5V and a negative voltage of −5V and supplies them to the level converter 100. Therefore, the control signal (VSIG) swinging from 0 V to 5V generated by the driving controller 300 is converted into the modified control signal (VMOD_SIG) swinging from −5V to 5V while passing through the level converter 100. Since the modified control signal (VMOD_SIG) operates the switch 250 with a voltage lower than the threshold voltage of the switch 250 of the switching converter 200 to completely block the switch 250. So, the current (IL) flowing through the inductor 210 does not flow over, unlike the simulation result of FIG. 5, and flows at about 2 A, which is the current level in the normal state of FIG. 4. The final output voltage (Vout) is normally output as a target voltage of about 39.8V.

That is, the switch 250 is not blocked by the control signal (VSIG) generated by the driving controller 300 since the electrical characteristics of the N-type MOSFET, which is the switch 250, are changed by radiation, but the modified control signal (VMOD_SIG) can sufficiently block the switch 250. Accordingly, even though the electrical characteristics of the switch element are changed due to exposure to the radioactive environment, the boost converter operates normally.

In this instance, a voltage lower than a source is applied to the gate in a case in which the switch 250 of the switching converter 200 is the N-type MOSFET, and a voltage higher than the source is applied to the gate in a case in which the switch 250 of the switching converter 200 is the P-type MOSFET, so that the voltage (VGS) applied between the gate and the source gets lower, thereby reducing a leakage current of the switch element.

In this instance, in the simulation using the first embodiment of the present disclosure, VDD and −VNN generated by the voltage generator respectively were 5V and −5V, but they are voltage values merely set for an illustrative purpose. In fact, different voltage values may be applied depending on the circuit characteristics of the power supply device.

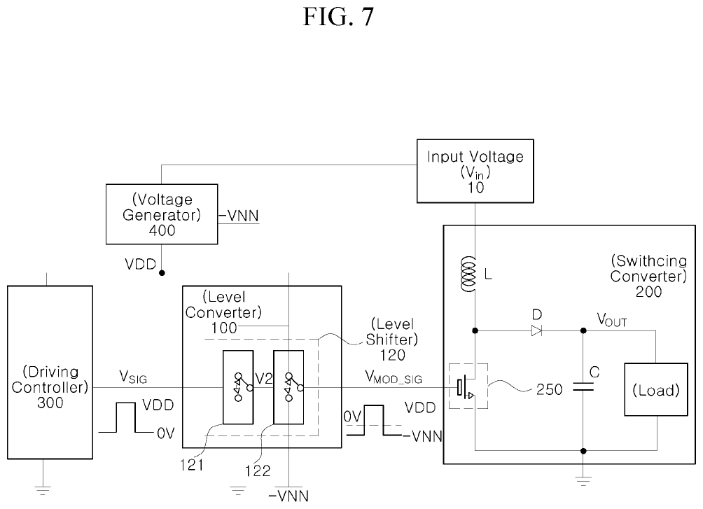

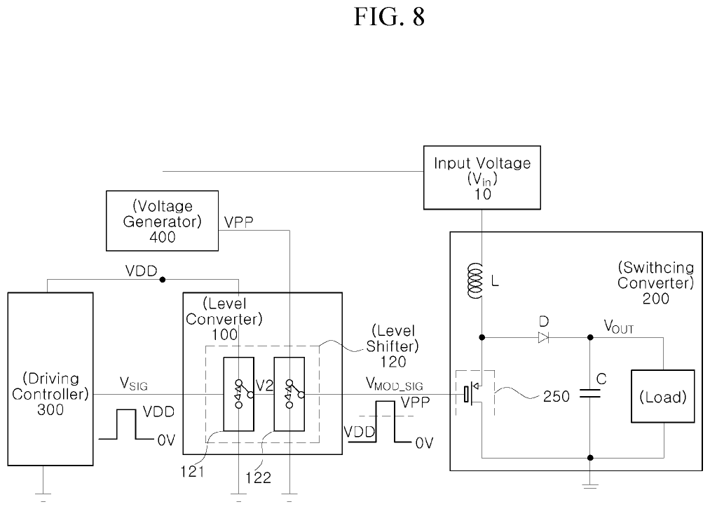

FIGS. 7 and 8 are circuit diagrams illustrating a case in which a level shifter 120 is used in a level converter implementing method according to an embodiment of the present disclosure. Specifically, FIG. 7 illustrates the level shifter 120 in a case in which the switch 250 is an N-type, and FIG. 8 illustrates the level shifter 120 in a case in which the switch 250 is a P-type. In addition, descriptions of parts that are the same as or similar to those described above may be omitted.

Referring to FIGS. 7 and 8, the level converter 100 according to an embodiment of the present disclosure receives a control signal (VSIG) from the driving controller 300, outputs a modified control signal (VMOD_SIG) to the switch 250 of the switching converter 100, is located between the driving controller 300 and the switch 250 of the switching converter 200, and includes the level shifter 120. In a case in which the control signal (VSIG) generated by the driving controller 300 is applied as input for the level shifter 120, the level shifter 120 changes the voltage level of the control signal (VSIG) for turning the switch 250 off, among the control signals (VSIG)_generated by the driving controller 300, by using the level shifting action, and generates the modified control signal (VMOD_SIG) of a modified voltage level.

Here, the switching converter 200 uses the input power of the input power unit 10, includes the switch 250, and generates output power by using the ON-OFF operation of the switch 250. The driving controller 300 generates a control signal (VSIG) for controlling the on-off operation of the switch 250 of the switching converter 200. The voltage generator 400 supplies power to at least one among the level converter 100, the switching converter 200, and the driving controller 300.

Specifically, the level shifter 120 generates a modified control signal (VMOD_SIG) having a modified voltage level by converting the voltage of the control signal (VSIG) for turning the switch 250 off, among the control signals (VSIG) to have a voltage level lower than the source terminal voltage of the switch 250 in the case in which the switch 250 is the N-type (See FIG. 7) and converting the voltage level of the control signal (VSIG) to have a voltage level higher than the source terminal voltage of the switch 250 in the case in which the switch 250 is the P-type (See FIG. 7), and applies the modified control signal (VMOD_SIG) to the gate terminal of the switch 250 of the switching converter 200.

The level shifter 120 includes a first level switch module 121 and a second level switch module 122.

The first level switch module 121 receives the control signal (VSIG) and outputs an intermediate control signal (V2) having a first swing range. The second level switch module 122 receives the intermediate control signal (V2) and outputs the modified control signal (VMOD_SIG) having a second swing range larger than the first swing range.

Here, in the case in which the switch 250 is the N-type, the voltage lower than the source terminal voltage of the switch 250 is not included in the first swing range and is included in the second swing range. In the case in which the switch 250 is the P-type, the voltage higher than the source terminal voltage of the switch 250 is not included in the first swing range and is included in the second swing range.

Accordingly, the level shifter 120 receives the control signal (VSIG) of the first swing range and generates the modified control signal (VMOD_SIG) to expand the swing range, thereby level-shifting to generate a desired control signal.

Referring to FIG. 7, in the case in which the switch 250 is the N-type, the first swing range of the control signal (VSIG) is, for example, between a voltage below a ground voltage generated by the voltage generator 400 and the first positive voltage (VDD) generated by the voltage generator 400. The first level switch module 121 outputs any one among the first positive voltage (VDD) generated by the voltage generator 400 and the voltage less than or equal to the ground voltage generated by the voltage generator 400 as the intermediate control signal (V2) according to the control signal (VSIG) of the first swing range. Therefore, the intermediate control signal (V2) also has the first swing range between the voltage below the ground voltage generated by the voltage generator 400 and the first positive voltage (VDD) generated by the voltage generator 400.

The second level switch module 122 outputs any one among a voltage equal to or higher than the first positive voltage (VDD) generated by the voltage generator 400 and the negative voltage (−VNN) generated by the voltage generator 400 according to the intermediate control signal (V2) which is output of the first level switch module 121, as the modified control signal (VMOD_SIG). Here, the negative voltage (−VNN) generated by the voltage generator 400 is lower than the source terminal voltage of the switch 250. That is, the second swing range of the modified control signal (VMOD_SIG) is between the voltage of the first positive voltage (VDD) generated by the voltage generator 400 and the negative voltage (−VNN) generated by the voltage generator 400, wherein the voltage higher than the first positive voltage (VDD) may be, for example, the first positive voltage (VDD) or the second positive voltage (VPP).

Accordingly, the level shifter 120 receives the control signal (VSIG) swinging between 0V generated by the driving controller 300 and the first positive voltage (VDD), and generates the modified control signal (VMOD_SIG) of the voltage level modified to −VNN, which is negative voltage lower than 0V applied to the source of the N-type MOSFET in a case in which the ground voltage, which is the voltage level of the control signal (VSIG) for turning the switch 250 off, is input.

Referring to FIG. 8, in a case in which the switch 250 is the P-type, the first swing range of the control signal (VSIG) may be, for example, between the voltage lower than the ground voltage generated by the voltage generator 400 and the first positive voltage (VDD) generated by the voltage generator 400. The first level switch module 121 outputs any one among the voltage lower than the ground voltage generated by the voltage generator 400 and the first positive voltage (VDD) generated by the voltage generator 400 as the intermediate control signal (V2) according to the control signal (VSIG) of the first swing range. Therefore, the intermediate control signal (V2) also has a first swing range between the voltage lower than the ground voltage generated by the voltage generator 400 and the first positive voltage (VDD) generated by the voltage generator 400.

In addition, the second level switch module 122 outputs any one among the voltage lower than the ground voltage generated by the voltage generator 400 and the second positive voltage (VPP) generated by the voltage generator 400 as the modified control signal (VMOD_SIG) according to the intermediate control signal (V2) which is output of the first level switch module 121. Here, the second positive voltage (VPP) generated by the voltage generator 400 is higher than the source terminal voltage of the switch 250. That is, the second swing range of the modified control signal (VMOD_SIG) may be between the second positive voltage (VPP) generated by the voltage generator 400 and the voltage lower than the ground generated by the voltage generator 400. The voltage lower than the ground may be, for example, a ground voltage or a negative voltage (−VNN).

Accordingly, the level shifter 120 receives the control signal (VSIG) moving between 0V generated by the driving controller 300 and the first positive voltage (VDD), and generates the modified control signal (VMOD_SIG) of the voltage level modified to VPP, which is the positive voltage higher than the first positive voltage (VDD) applied to the source of the P-type MOSFET, in a case in which the first positive voltage (VDD), which is the voltage level of the control signal (VSIG) for turning the switch 250 off, is input.

Referring to FIG. 9, an example circuit diagram of the level shifter 120 in a case in which the switch 250 is an N-type will be described. FIG. 9 is a circuit diagram of the level shifter 120 of FIG. 7.

The level shifter 120 includes a first level switch module 121, a second level switch module 122, and an amplifier 123, and receives the control signal (VSIG) to output the modified control signal (VMOD_SIG).

FIG. 9 illustrates a Class B amplifier (Class B AMP) as the amplifier 123, but may be another one different from the amplifier of FIG. 9 if it can perform the function corresponding to that of the amplifier 123. The amplifier 123 is connected to an output terminal (V4) of the second level switch module 122, modifies and amplifies an input signal. The modified control signal (VMOD_SIG) is output to the switch 250 of the switching converter 200 through the amplifier 123. For instance, the amplifier 123 includes an NPN-type BJT (Q2) and a PNP-type BJT (Q3). The output terminal (V4) of the second level switch module 122 is connected to bases of the NPN-type BJT (Q2) and the PNP-type BJT (Q3), a collector of the NPN-type BJT (Q2) is connected to the positive voltage (VDD) generated by the voltage generator 400, and an emitter of the NPN-type BJT (Q2) is connected to the output terminal of the level shifter 120. A collector of the PNP-type BJT (Q3) is connected to the negative voltage (−VNN) generated by the voltage generator 400, and an emitter of the PNP-type BJT (Q3) is connected to the output terminal of the level shifter 120.

In a case in which the switch 250 is an N-type, the level converter 100 includes: a first level switch (Q0) which is connected between the positive voltage (VDD) generated by the voltage generator 400 and the ground voltage (GND) generated by the voltage generator 400 and outputs the positive voltage (VDD) as the intermediate control signal (V2) when the voltage level of the control signal (VSIG) for turning the switch 250 off is input; and a second level switch (Q1) which performs an on-off action according to the intermediate control signal (V2) depending on the operation of the first level switch (Q0), is connected between the voltage higher than the positive voltage (VDD) generated by the voltage generator 400 and the negative voltage (−VNN) generated by the voltage generator 400, and outputs the negative voltage (−VNN) lower than the source terminal voltage of the switch 250 as the modified control signal (VMOD_SIG) when the positive voltage (VDD) is input as the intermediate control signal (V2). A circuit including the first level switch (Q0) is included in the first level switch module 121 of FIG. 7, and a circuit including the second level switch (Q1) is included in the second level switch module 122.

Here, the negative voltage (−VNN) generated by the voltage generator 400 is lower than the source terminal voltage of the switch 250.

Moreover, the first level switch module 121 further includes a first load circuit 124 of which one end receives the control signal (VSIG) and the other end is connected to the first level switch (Q0), and the second level switch module 122 further includes a second load circuit 125 of which one end receives the intermediate control signal (V2) and the other end is connected to the second level switch (Q1). For example, the other end of the first load circuit 124 is connected to the base of the first level switch (Q0), and the other end of the second load circuit 125 is connected to the base of the second level switch (Q1).

The control signal (VSIG) is input to the first level switch (Q0) via the first load circuit 124, and the intermediate control signal (V2) is input to the second level switch (Q1) via the second load circuit 125. Here, each of the first and second load circuits 124 and 125 may include a resistor or a resistor-capacitor parallel circuit.

In addition, In FIG. 9, the first and second level switches (Q0 and Q1) are different types of bipolar junction transistors (BJTs), but the present disclosure is not limited thereto. The first and second level switches (Q0 and Q1) may be semiconductor switch elements. The semiconductor switch element may be an N-type or P-type metal-oxide-semiconductor field effect transistor (MOSFET), an NPN-type or PNP-type BJT, or an insulated gate bipolar transistor (IGBT).

Specifically, the voltage, for instance, the ground voltage, of the control signal (VSIG) for turning the switch 250 off is transmitted to V1 through an RC parallel circuit (R0 and C0) of the first load circuit 124 and is input to the base of the first level switch (Q0), so that the first level switch (Q0) is turned off. The voltage, for instance, the positive voltage (VDD), of the control signal (VSIG) for turning on the switch 250 is transmitted to V1 through the RC parallel circuit (R0 and C0) of the first load circuit 124 and is input to the base of the first level switch (Q0), so that the first level switch (Q0) is turned on. Here, the RC parallel circuit (R0 and C0) of the first load circuit 124 may function as a filter, and A circuit (R0) instead of the RC parallel circuit (R0 and C0) may be used.

The collector of the first level switch (Q0), which is one end (V2) of the first level switch (Q0), is connected to the ground voltage (GND) generated by the voltage generator 400 when the first level switch (Q0) is turned on, and is connected to the positive voltage (VDD) generated by the voltage generator 400 through the resistor (R1) when the first level switch (Q0) is turned off.

Here, in a case in which the first level switch (Q0) is an NPN-type BJT, the base of the first level switch (Q0) is connected to the RC parallel circuit (R0 and C0) of the first load circuit 124, and the emitter of the first level switch (Q0) is connected to the ground voltage (GND) generated by the voltage generator 400.

The collector, which is one end (V2) of the first level switch (Q0), is connected to the positive voltage (VDD) generated by the voltage generator 400 through the resistor (R1), and is connected to the second level switch (Q1) through the RC parallel circuit (R2 and C1) of the second load circuit 125 at the same time. An end of the resistor (R1) is connected to the collector (V2) of the first level switch (Q0), and the other end of the resistor (R1) is connected to the positive voltage (VDD) generated by the voltage generator 400.

The second level switch (Q1) is turned on when the first level switch (Q0) is turned on, and is turned off when the first level switch (Q0) is turned off. Here, a circuit (R2) instead of the RC parallel circuit (R0 and C0) may be used.

Meanwhile, in a case in which the second level switch (Q1) is a PNP type BJT, the base of the second level switch (Q1) is connected to the RC parallel circuit (R2 and C1) of the second load circuit 125, the emitter of the second level switch (Q1) is connected to the positive voltage (VDD) generated by the voltage generator 400, and the collector of the second level switch (Q1) is connected to the negative voltage (−VNN) generated by the voltage generator 400 through the resistor (R3). That is, the collector of the second level switch (Q1) is connected to an end of the resistor (R4) and the amplifier 123, and the other end of the resistor (R4) is connected to the negative voltage (−VNN) generated by the voltage generator 400.

When the first level switch (Q0) is turned off, one end (V2) of the first level switch (Q0) is connected to the positive voltage (VDD) generated by the voltage generator 400 through the resistor (R1), and the voltage level of one end (V2) of the first level switch (Q0) becomes a positive voltage (VDD). Accordingly, the second level switch (Q1) is turned off, so that the end (V4) of the second level switch (Q1) is connected to the negative voltage (−VNN) generated by the voltage generator 400, which is lower than the source terminal voltage of the switch 250, to output the modified control signal (VMOD_SIG) through the amplifier 123. That is, the first end (V4) of the second level switch (Q1) is connected to the positive voltage (VDD) generated by the voltage generator 400 when the second level switch (Q1) is turned on, and the first end (V4) of the second level switch (Q1) is connected to the negative voltage (−VNN) generated by the voltage generator 400 when the second level switch (Q1) is turned off.

The end (V4) of the second level switch (Q1) is connected to the amplifier 123 to output the modified control signal (VMOD_SIG), which is corrected and amplified through the amplifier 123.

Accordingly, the level converter 100 outputs the modified control signal (VMOD_SIG) obtained by converting the control signal (VSIG) of 0 to VDD into the control signal of −VNN to VDD to extend the swing width.

Meanwhile, in a case in which the switch 250 is a P-type, the level converter 100 includes a first level switch turning on and off according to the control signal (VSIG), and a second level switch turning on and off according to the operation of the first level switch. When the voltage of the control signal (VSIG) for turning the switch 250 off is input to the first level switch, one end of the second level switch is connected to the voltage higher than the source terminal voltage of the switch 250 to convert the voltage of the control signal (VSIG) for turning the switch 250 off into the voltage higher than the source terminal voltage of the switch 250, thereby generating the modified control signal (VMOD_SIG).

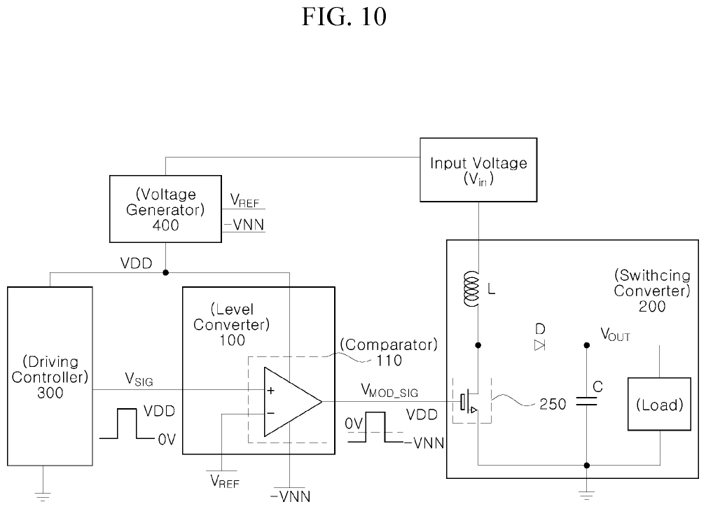

FIG. 10 is a circuit diagram illustrating a case in which a comparator 110 is used in the level converter implementing method according to an embodiment of the present disclosure. In this embodiment, descriptions of parts that are the same as or similar to those described above may be omitted.

The comparator 110 of the level converter 100 of FIG. 10 may be substituted with an operational amplifier. The level converter includes any one among the operational amplifier and the comparator 110. A power source of the operational amplifier or the comparator 110 is a voltage generated by the voltage generator 400. The control signal (VSIG) generated by the driving controller 300 is applied to an input of the operational amplifier or the comparator 110. A reference voltage (VREF) generated by the voltage generator 400 in order to change and output the voltage level of the control signal (VSIG) generated by the driving controller is applied to the other one among the operational amplifier and the comparator 110. Thereafter, the comparator 110 compares the two received signals with each other, generates a modified control signal (VMOD_SIG) having a modified voltage level by converting the voltage of the control signal (VSIG) generated by the driving controller 300 in the blocking section to have a voltage level (negative voltage) lower than the source terminal voltage of the switch 250 in a case in which the switch 250 of the switching converter 200 is a N-type MOSFET and converting the voltage of the control signal (VSIG) to have a voltage level higher than the source terminal voltage of the switch 250 in a case in which the switch 250 of the switching converter is a P-type MOSFET, and then, applies the modified control signal to the gate terminal of the switch 250 of the switching converter 200.

In more detail, as illustrated in FIG. 10, the level converter 100 according to the embodiment in which the switch 250 of the switching converter 200 is the N-type MOSFET uses the comparator 110 using the positive voltage (VDD) and the negative voltage (−VNN) generated by the voltage generator 400 as a power source. The comparator 110 receives the control signal (VSIG) generated by the driving controller 300 as positive input and receives the reference voltage (VREF) generated by the voltage generator 400 as negative input. Accordingly, when the control signal (VSIG) generated by the driving controller 300 swings from 0V to VDD, the comparator outputs VDD in the voltage section where the voltage of the control signal (VSIG) is higher than the reference voltage (VREF) and outputs −VNN in the voltage section where the voltage of the control signal (VSIG) is lower than the reference voltage (VREF), so that the control signal (VSIG) swinging from 0V to VDD is converted into the modified control signal (VMOD_SIG) swinging from −VNN to VDD.

In this instance, as an example, VREF is set to be an intermediate voltage value between VDD and 0V according to the circuit characteristics of the power supply device. However, the voltage value of VREF can be changed according to characteristics of the circuit.

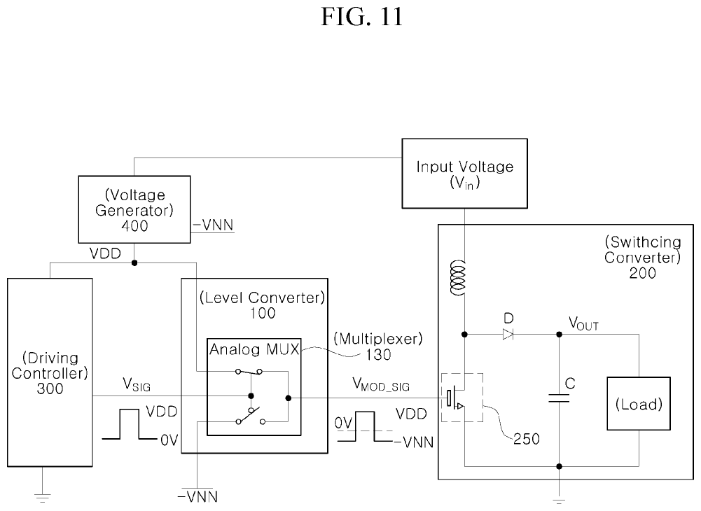

FIG. 11 is a circuit diagram illustrating a case in which a multiplexer 130 is used in the level converter implementing method according to an embodiment of the present disclosure. In this embodiment, descriptions of parts that are the same as or similar to those described above may be omitted.

In FIG. 11, the level converter 100 includes a multiplexer 130. The level converter 100 connects the voltage generated by the voltage generator 400 to ends of switches of the multiplexer 130, and applies the control signal generated by the driving controller 300 to input sides of the switches complementarily acting in the multiplexer 130. Thereafter, the level converter 100 generates a modified control signal (VMOD_SIG) having a modified voltage level by converting the voltage of the control signal (VSIG) received through the switching action of the multiplexer 130 and generated by the driving controller 300 in the blocking section to have a voltage level (negative voltage) lower than the source terminal voltage of the switch 250 in a case in which the switch 250 of the switching converter 200 is a N-type MOSFET and converting the voltage of the control signal (VSIG) to have a voltage level higher than the source terminal voltage of the switch 250 in a case in which the switch 250 of the switching converter is a P-type MOSFET, and then, applies the modified control signal to the gate terminal of the switch 250 of the switching converter 200.

In more detail, as illustrated in FIG. 11, the level converter 100 according to the embodiment in which the switch 250 of the switching converter 200 is the N-type MOSFET uses a multiplexer 130 using the positive voltage (VDD) and the negative voltage (−VNN) generated by the voltage generator 400 as a power source. The multiplexer 130 forms a circuit using analog switches performing a complementary action. Ends of switches of the multiplexer 130 are respectively connected to VDD and −VNN, and the control signal (VSIG) generated by the driving controller 300 becomes a selective signal of the multiplexer 130. In a case in which the input voltage of the control signal (VSIG) is VDD, the output voltage is VDD. In a case in which the input voltage of the control signal (VSIG) is 0V, −VNN is output, and then, a modified control signal (VMOD_SIG) that the output voltage of the level converter 100 is converted into −VNN to VDD is output.

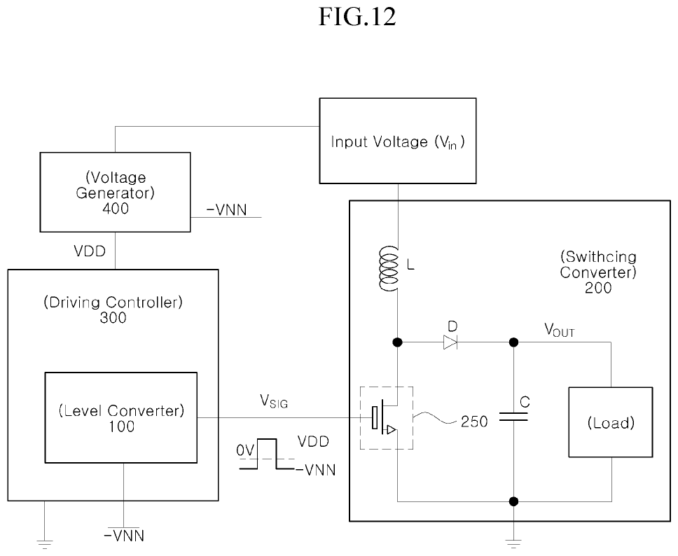

FIG. 12 is a circuit diagram illustrating a case in which a level converter is embedded in a driving control unit in the level converter implementing method according to an embodiment of the present disclosure. In this embodiment, descriptions of parts that are the same as or similar to those described above may be omitted.

In FIG. 12, the level converter 100 is included in the circuit of the driving controller 300. An IC chip is manufactured by embedding a circuit of the level converter 100 in an IC chip of the driving controller. In order to block the switch 250 of the switching converter 200, in a case in which the switch 250 of the switching converter 200 is an N-type MOSFET, the IC chip converts the voltage in the blocking section of the control signal (VSIG) into the voltage (negative voltage) lower than the source terminal voltage of the switch 250. In a case in which the switch 250 of the switching converter 200 is a P-type MOSFET, the IC chip generates the voltage higher than the source terminal voltage of the switch 250 and applies the voltage to the gate terminal of the switch 250 of the switching converter 200.

In more detail, as illustrated in FIG. 12, the level converter 100 according to the embodiment in which the switch 250 of the switching converter 200 is the N-type MOSFET is included in the driving controller 300. That is, the circuit of the level converter 100 is embedded in the IC chip of the driving controller 300, so that the voltage level of the control signal (VSIG) generated by the driving controller 300 is output not to move from 0V to VDD but to swing from −VNN to VDD. In this instance, as an example, the circuit of the level converter 100 included in the circuit of the driving controller 300 is embedded in the IC chip of the driving controller 300 by using the circuit of any one among the level converters 100 of FIGS. 9 to 11 so as to manufacture an IC chip. In order to block the switch 250 of the switching converter 200, in a case in which the switch 250 of the switching converter 200 is an N-type MOSFET, the IC chip converts the voltage in the blocking section into the voltage (negative voltage) lower than the source terminal voltage of the switch 250. In a case in which the switch 250 of the switching converter 200 is a P-type MOSFET, the IC chip generates the voltage higher than the source terminal voltage of the switch 250 and applies the voltage to the gate terminal of the switch 250 of the switching converter 200.

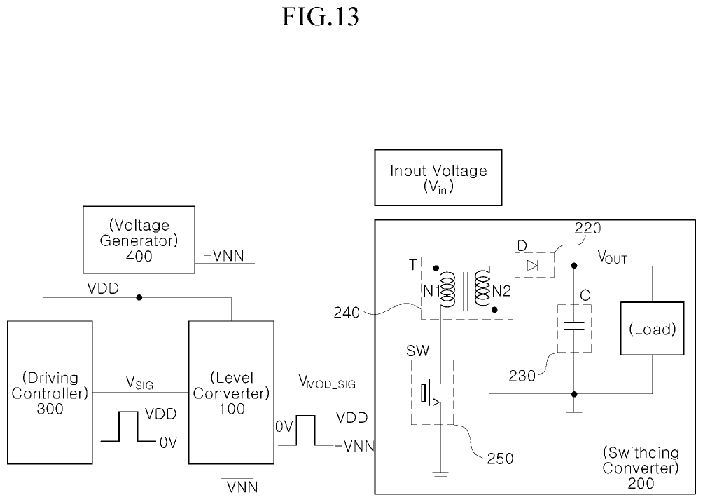

FIG. 13 is a circuit diagram illustrating a flyback converter according to a second embodiment of the present disclosure. Referring to FIG. 13, the flyback converter according to the second embodiment of the present disclosure includes a switching converter 200 having a transformer (T) 240, a diode 220, a capacitor 230, and a switch 250, a level converter 100, a driving controller 300, and a voltage generator 400. In this embodiment, descriptions of parts that are the same as or similar to those described above may be omitted.

The flyback converter is an insulated power converter, and the operation of the flyback converter will be described as follows. The voltage generator generates power and supplies the power to the driving controller 300 and the level converter 100. The driving controller 300 generates a control signal (VSIG) in order to control the switch 250 of the switching converter 200. The generated control signal (VSIG) is converted into a modified control signal (VMOD_SIG) having a voltage level modified through the level converter 100. In this instance, in order to block the switch 250 of the switching converter 200 and reduce a leakage current of the switch, the level converter 100 converts the control signal (VSIG) generated by the driving controller 300 in the blocking section into the modified control signal (VMOD_SIG) having the modified voltage level by changing the voltage of the control signal (VSIG) into the voltage lower than the source terminal voltage of the switch in a case in which the switch 250 of the switching converter 200 is an N-type MOSFET and changing the voltage of the control signal (VSIG) into the voltage higher than the source terminal voltage of the switch 250 in a case in which the switch 250 of the switching converter 200 is a P-type MOSFET, and then, applies the modified voltage to the gate terminal of the switch 250. In this instance, when the switch 250 is connected by the modified control signal (VMOD_SIG), the current flows to a first coil of the transformer 240, and an input voltage is induced to the coil. In this instance, a voltage proportional to the turn ratio (n; N1:N2) is applied to a second coil. However, the voltage is applied in the reverse direction of the diode 220. Finally, energy is accumulated only at a magnetized inductance of the first coil. Thereafter, when the switch 250 is blocked by the control signal, the voltage having the polarity opposed to the above state is induced to the second coil so that the diode 220 is connected electrically. Accordingly, the current flows to the second coil, and the energy accumulated at the magnetized inductance of the transformer is output, thereby supplying the output voltage to the load.

In this instance, in a case in which the switch 250 of the switching converter 200 is an N-type MOSFET, the voltage lower than the source voltage is applied to the gate, and in a case in which the switch 250 of the switching converter 200 is a P-type MOSFET, the voltage higher than the source voltage is applied to the gate, so that the voltage (VGS) applied between the gate and the source gets lower, thereby reducing a leakage current of the switch element.

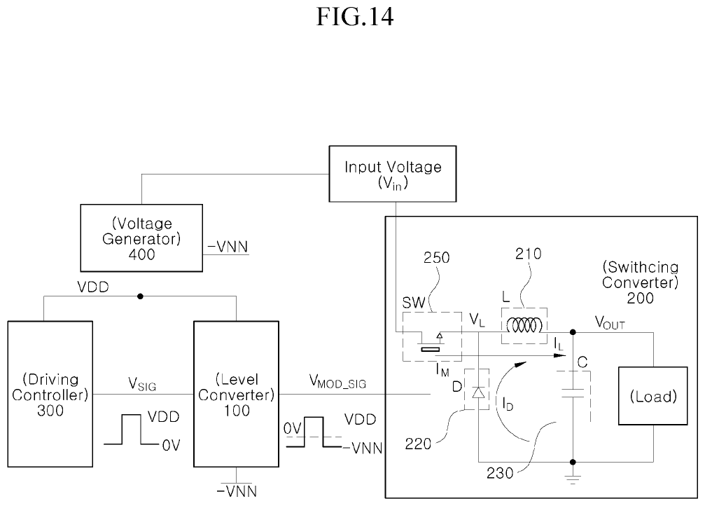

FIG. 14 is a circuit diagram illustrating a buck converter according to a third embodiment of the present disclosure. Referring to FIG. 14, the buck converter according to the third embodiment of the present disclosure includes a switching converter 200 having an inductor 210, a diode 220, a capacitor 230, and a switch 250, a level converter 100, a driving controller 300, and a voltage generator 400. In this embodiment, descriptions of parts that are the same as or similar to those described above may be omitted.

The buck converter is an SMPS lowering and outputting the input voltage, and determines the size of the output voltage (Vout) based on the input voltage (Vin) by controlling the on-off duty ratio of the switch 250 through the control signal.

$$VOUT = D * VIN ( D : duty ratio ) \qquad [ Equation 2 ]$$

The operation of the buck converter according to the embodiment will be described as follows. The voltage generator 400 generates power and supplies power to the driving controller 300 and the level converter 100. The driving controller 300 generates a control signal (VSIG) to control the switch 250 of the switching converter 200. The generated control signal (VSIG) is converted into a modified control signal (VMOD_SIG) of a voltage level modified through the level converter 100. In this instance, in order to block the switch 250 of the switching converter 200 and reduce a leakage current of the switch, the level converter 100 converts the control signal (VSIG) generated by the driving controller 300 in the blocking section into the modified control signal (VMOD_SIG) having the modified voltage level by changing the voltage of the control signal (VSIG) into the voltage lower than the source terminal voltage of the switch in a case in which the switch 250 of the switching converter 200 is an N-type MOSFET and changing the voltage of the control signal (VSIG) into the voltage higher than the source terminal voltage of the switch 250 in a case in which the switch 250 of the switching converter 200 is a P-type MOSFET, and then, applies the modified voltage to the gate terminal of the switch 250. In this instance, when the switch 250 is connected by the modified control signal (VMOD_SIG), energy is stored in the inductor 210 while the current (IM) passing through the switch 250 from the input voltage (Vin) does not flow toward the diode 220 (ID≈0) but only the current (IL) passing through the inductor 210 flows (IM≈IL). Thereafter, in a case in which the switch 250 is blocked by the control signal, energy supply from the input voltage (Vin) is stopped and the energy accumulated in the inductor 200 flows through the capacitor 230 and the diode 220, so that the output voltage (Vout) is leveled through an LC filter and is stepped down to be lower than the input voltage (Vin).

According to an embodiment of the present disclosure, the power supply device and the driving method thereof can prevent the power supply device of the electronic device used in a space, in which environmental stress may be generated, from malfunction or destruction caused by the environmental stress, thereby stably supplying electric power to the electronic device even in the stress environment.

Moreover, according to an embodiment of the present disclosure, the present disclosure allows a user to use an electronic device even in the environment in which the power supply device may be destroyed.

In addition, according to an embodiment of the present disclosure, the present disclosure can reduce a leakage current of a semiconductor switch element used in the power supply device.

The advantages of the present disclosure are not limited to the above-mentioned advantages, and other advantages, which are not specifically mentioned herein, will be clearly understood by those skilled in the art from the following description.

The method or algorithm described in relation to the embodiments of the present disclosure can be directly embodied in hardware, can be embodied in a software module executed by hardware, or can be embodied by combination thereof. The software module can reside in a random access memory (RAM), a read-only memory (ROM), an erasable programmable read-only memory (EPROM), an electrically erasable programmable read-only memory (EEPROM), a flash memory, a hard disk, a detachable disk, a CD-ROM, or a medium readable by a computer, well-known in the technical field to which the present disclosure belongs.

The above description is only exemplary, and it will be understood by those skilled in the art that the disclosure may be embodied in other concrete forms without changing the technological scope and essential features. Therefore, the above-described embodiments should be considered only as examples in all aspects and not for purposes of limitation.

1. A power supply device comprising:
a switching converter using input power of AC or DC supplied through an input power unit, having a switch, and generating output power by using an on-off action of the switch;
a driving controller generating a first control signal for controlling the on-off action of the switch of the switching converter;
a level converter receiving the first control signal from the driving controller, outputting a second control signal to the switch of the switching converter, and including a level shifter generating the second control signal having a modified voltage level by converting a voltage of the first control signal for turning the switch off to have a voltage level lower than source terminal voltage of the switch in a case in which the switch of the switching converter is an N-type and by converting the voltage to voltage higher than the source terminal voltage of the switch in a case in which the switch of the switching converter is a P-type; and
a voltage generator supplying a power source to at least one among the switching converter, the driving controller, and the level converter.

2. The power supply device according to claim 1, wherein the level shifter comprises:
a first level switch module receiving the first control signal and outputting an intermediate control signal having a first swing range; and
a second level switch module receiving the intermediate control signal and outputting the second control signal having a second swing range wider than the first swing range, and
wherein in the case in which the switch is the N-type, the voltage lower than the source terminal voltage of the switch is not included in the first swing range but is included in the second swing range, and in the case in which the switch is the P-type, the voltage higher than the source terminal voltage of the switch is not included in the first swing range but is included in the second swing range.

3. The power supply device according to claim 2, wherein the first control signal has the first swing range.

4. The power supply device according to claim 2, wherein the first level switch module outputs any one among a first positive voltage generated by the voltage generator and a ground voltage generated by the voltage generator as the intermediate control signal according to the first control signal,
wherein the second level switch module outputs any one among the voltage higher than the first positive voltage generated by the voltage generator and a negative voltage generated by the voltage generator as the second control signal according to the intermediate control signal in the case in which the switch is the N-type, and outputs any one among a second positive voltage generated by the voltage generator and a voltage lower than the ground voltage as the second control signal according to the intermediate control signal in the case in which the switch is the P-type,
wherein the negative voltage is lower than the source terminal voltage of the switch, and
wherein the second positive voltage is higher than the first positive voltage and the source terminal voltage of the switch.

5. The power supply device according to claim 2, wherein the first level switch module includes a first level switch performing an on-off action according to the first control signal, and
wherein in the case in which the switch is the N-type, the first level switch is connected between the first positive voltage generated by the voltage generator and the ground voltage generated by the voltage generator, and the first positive voltage generated by the voltage generator is connected through a resistor at the first level switch, and
wherein the first level switch outputs the first positive voltage as the intermediate control signal when the voltage level of the first control signal for turning the switch off is input.

6. The power supply device according to claim 5, wherein the second level switch module includes a second level switch performing an on-off action according to the first control signal, and
wherein the second level switch is connected between a voltage higher than the first positive voltage generated by the voltage generator and a negative voltage generated by the voltage generator, and the negative voltage generated by the voltage generator is connected through a resistor at the second level switch, and
wherein the second level switch outputs the negative voltage, which is lower than the source terminal voltage of the switch, as the second control signal when the first positive voltage is input to the intermediate control signal.

7. The power supply device according to claim 6, wherein the first level switch module further includes a first load circuit of which one end receives the first control signal and the other end is connected to the first level switch,
wherein the second level switch module further includes a second load circuit of which one end receives the intermediate control signal and the other end is connected to the second level switch, and
wherein the first control signal is input to the first level switch passing through the first load circuit, and the intermediate control signal is input to the second level switch passing through the second load circuit.

8. The power supply device according to claim 7, wherein each of the first and second load circuits includes a resistor or a resistor-capacitor parallel circuit.

9. The power supply device according to claim 7, wherein the first level switch and the second level switch are different types of bipolar junction transistors (BJTs).

10. The power supply device according to claim 7, further comprising:
an amplifier having an end connected to an output terminal of the second level switch module, and modifying and amplifying an input signal,
wherein the second control signal is output to the switch of the switching converter through the amplifier.

11. A power supply device comprising:
a switching converter using input power of AC or DC supplied through an input power unit, having a switch, and generating output power by using an on-off action of the switch;
a driving controller generating a first control signal for controlling the on-off action of the switch of the switching converter;
a level converter disposed between the driving controller and the switching converter to control the on-off action of the switch, generating a second control signal having a modified voltage level by converting a voltage of the first control signal generated by the driving controller to turn off the switch to have a voltage level lower than a source terminal voltage of the switch in a case in which the switch is an N-type and converting the voltage of the first control signal to have a voltage level higher than the source terminal voltage of the switch to in a case in which the switch is a P-type, and applying the second control signal to a gate terminal of the switch of the switching converter; and
a voltage generator supplying a power source to at least one among the switching converter, the driving controller, and the level converter.

12. The power supply device according to claim 11, wherein the level converter comprises any one among an operational amplifier and a comparator, applies the first control signal generated by the driving controller to an input of the operational amplifier or the comparator and applies a reference voltage generated by the voltage generator to the other input of the operational amplifier or the comparator, and then, compares the two signals with each other,
wherein in the case in which the switch of the switching converter is the N-type, the level converter converts the voltage of the first control signal, which is lower than the reference voltage, to have a voltage level lower than the source terminal voltage of the switch,
wherein in the case in which the switch of the switching converter is the P-type, the level converter converts the voltage of the first control signal, which is higher than the reference voltage, to have a voltage level higher than the source terminal voltage of the switch, and
wherein the level converter converts the first control signal generated by the driving controller into the second control signal having the modified voltage level, and outputs and applies the second control signal to the gate terminal of the switch of the switching converter.

13. The power supply device according to claim 12, wherein the level converter is included in a circuit of the driving controller, and is manufactured in an IC chip by embedding a circuit of the level converter in an IC chip of the driving controller,
wherein in the case in which the switch of the switching converter is the N-type, the level converter outputs the voltage of the control signal for turning the switch off, among the first control signals generated to control the on-off action of the switch of the switching converter, to have a voltage level lower than the source terminal voltage of the switch,
wherein in the case in which the switch of the switching converter is the P-type, the level converter outputs the voltage of the first control signal to have a voltage level higher than the source terminal voltage of the switch, and applies the control signal to the gate terminal of the switch.

14. The power supply device according to claim 12, wherein the switching converter comprises:
a first switch element controlling a flow of a current;
any one among a second switch element and a diode controlling the flow of the current while operating complementarily with the first switch element;
a capacitor storing energy; and
a switched mode power supply (SMPS) including any one among a transformer and an inductor storing energy, and
wherein the switching converter controls the voltage of the control signal for turning the switch off, among the first control signals generated to control the on-off action of the first switch element, to have a voltage level lower than the source terminal voltage of the switch in the case in which the switch of the switching converter is the N-type, and controls the voltage of the control signal to have a voltage level higher than the source terminal voltage of the switch in the case in which the switch of the switching converter is the P-type.

15. The power supply device according to claim 14, wherein the switched mode power supply comprises:
a flyback converter including a switch element and a transformer, insulating an input side and an output side using the switch element and the transformer, and outputting any one among a voltage higher than an input voltage and a voltage lower than the input voltage;
a buck converter including a switch element and outputting a voltage lower than the input voltage;
a boost converter including a switch element and outputting a voltage higher than the input voltage; and
one of boost-buck converters including a switch element and outputting any one among a voltage lower than the input voltage and a voltage higher than the input voltage, and
wherein the switched mode power supply controls the voltage of the control signal for turning the switch off, among the first control signals generated to control the on-off action of the switch element, to have a voltage level lower than the source terminal voltage of the switch in the case in which the switch of the switching converter is the N-type, and controls the voltage of the control signal to have a voltage level higher than the source terminal voltage of the switch in the case in which the switch of the switching converter is the P-type.

16. The power supply device according to claim 12, wherein the switching converter is a linear regulator including a switch element, and controls the voltage of the control signal for turning the switch off, among the first control signals generated to control the on-off action of the first switch element, to have a voltage level lower than the source terminal voltage of the switch in the case in which the switch of the switching converter is the N-type, and controls the voltage of the control signal to have a voltage level higher than the source terminal voltage of the switch in the case in which the switch of the switching converter is the P-type.

17. A power supply device comprising:
a switching converter using input power of AC or DC supplied through an input power unit, having a switch, and generating output power by using an on-off action of the switch;
a driving controller generating a first control signal for controlling the on-off action of the switch of the switching converter;
a level converter disposed between the driving controller and the switching converter to control the on-off action of the switch, generating a second control signal by converting a voltage of the first control signal generated by the driving controller to turn off the switch into a modified voltage, and applying the modified control signal to a gate terminal of the switch of the switching converter; and
a voltage generator supplying a power source to at least one among the switching converter, the driving controller, and the level converter.

18. The power supply device according to claim 17, wherein the level converter includes a multiplexer, applies the first control signal generated by the driving controller to input sides of switches operating complementarily with each other in the multiplexer, generates a second control signal having a modified voltage level by converting a voltage of the first control signal generated by the driving controller to turn off the switch to have a voltage level lower than a source terminal voltage of the switch in a case in which the switch of the switching converter is an N-type and converting the voltage of the first control signal to have a voltage level higher than the source terminal voltage of the switch to in a case in which the switch of the switching converter is a P-type so as to generate a second control signal with a modified voltage level, and then, applies the second control signal to a gate terminal of the switch of the switching converter.
